(19) United States
(12) Patent Application Publication
(10) Pub. No.: US 2025/0107284 A1
(43) Pub. Date: Mar. 27, 2025

(54) ELECTRO-OPTICAL DEVICE AND ELECTRONIC DEVICE

(71) Applicant: SEIKO EPSON CORPORATION, Tokyo (JP)

(72) Inventors: Yuiga HAMADE, Matsumoto-shi (JP); Narumi ISHIBASHI, Shiojiri-shi (JP); Hitoshi OTA, Shiojiri-shi (JP)

(73) Assignee: SEIKO EPSON CORPORATION, Tokyo (JP)

(21) Appl. No.: 18/891,489

(22) Filed: Sep. 20, 2024

(30) Foreign Application Priority Data
Sep. 22, 2023 (JP) 2023-158085

(51) Int. Cl. H01L 33/38; G02B 27/01; H01L 33/62

(52) U.S. Cl. CPC H10H 20/8312; G02B 27/0172; H10H 20/857; G02B 2027/0178

(57) ABSTRACT

An electro-optical device includes a common electrode; a plurality of structural bodies, each including a first semiconductor layer electrically coupled to the first electrode, a second semiconductor layer, and a light emission function layer provided between the first semiconductor layer and the second semiconductor layer; and a driving printed wired board including a pixel electrode and a driving circuit electrically coupled to the pixel electrode. The plurality of structural bodies include a first structural body provided at a position overlapping the pixel electrode in plan view, the pixel electrode being electrically coupled to the second semiconductor layer, and a second structural body provided at a position not overlapping the pixel electrode in plan view, the pixel electrode not being electrically coupled to the second semiconductor layer.

The present application is based on, and claims priority from JP Application Serial Number 2023-158085, filed Sep. 22, 2023, the disclosure of which is hereby incorporated by reference herein in its entirety.

### BACKGROUND

### 1. Technical Field

The present disclosure relates to an electro-optical device and an electronic device.

### 2. Related Art

There is known a micro light-emitting diode (LED) display device including a micro LED panel in which a plurality of micro LED pixels are formed, and a micro LED driving substrate that individually drives the micro LEDs (refer to, for example, JP-A-2018-185515, FIG. 18). The micro LED driving substrate includes complementary metal oxide semiconductor (CMOS) cells (driving circuits) for individually driving the micro LED pixels, and bumps for electrically coupling the CMOS cells to the micro LED pixels.

In the plurality of micro LED pixels, one electrode is a common electrode, and the other electrode faces the micro LED driving substrate. Then, the micro LED panel and the micro LED driving substrate are bonded to each other with the other electrodes of the micro LED pixels being coupled to the bumps of the micro LED driving substrate.

However, in the technique described in JP-A-2018-185515, there is a problem in that, when the micro LED driving substrate and the micro LED panel are brought into close contact and bonded to each other, positioning is extremely strict.

### SUMMARY

According to an aspect of the present disclosure, an electro-optical device includes a first electrode; a plurality of structural bodies, each including a first semiconductor layer having a first conductivity type electrically and being coupled to the first electrode, a second semiconductor layer of a second conductivity type, and a light emission function layer provided between the first semiconductor layer and the second semiconductor layer and configured to emit light by being injected with current; and a substrate including a second electrode and a driving circuit electrically coupled to the second electrode. The plurality of structural bodies include a first structural body provided at a position overlapping the second electrode in plan view, the second electrode being electrically coupled to the second semiconductor layer, and a second structural body provided at a position not overlapping the second electrode in plan view, the second electrode not being electrically coupled to the second semiconductor layer.

### BRIEF DESCRIPTION OF THE DRAWINGS

FIG. 1 is a cross-sectional view schematically illustrating an electro-optical device according to an embodiment.

FIG. 2 is a cross-sectional view schematically illustrating the electro-optical device according to the embodiment.

FIG. 3 is a cross-sectional view schematically illustrating the electro-optical device according to the embodiment.

FIG. 4 is a plan view illustrating a buffer layer, a pixel electrode, and the like in the electro-optical device.

FIG. 5 is a cross-sectional view illustrating a structure of a structural body of the electro-optical device.

FIG. 6 is a plan view illustrating a positional relationship of the structural bodies and the buffer layer in the electro-optical device.

FIG. 7 is a perspective view illustrating a head-mounted display that uses the electro-optical device.

FIG. 8 is a diagram illustrating an optical configuration of the head-mounted display.

### DESCRIPTION OF EMBODIMENTS

An electro-optical device according to an embodiment will be described below with reference to the accompanying drawings. Note that, in each of the drawings, dimensions and a scale of each part are appropriately different from actual ones. Moreover, the embodiment described below is a suitable specific example, and various technically preferable limitations are applied, but the scope of the disclosure is not limited to these modes unless they are specifically described in the following description as limiting the disclosure.

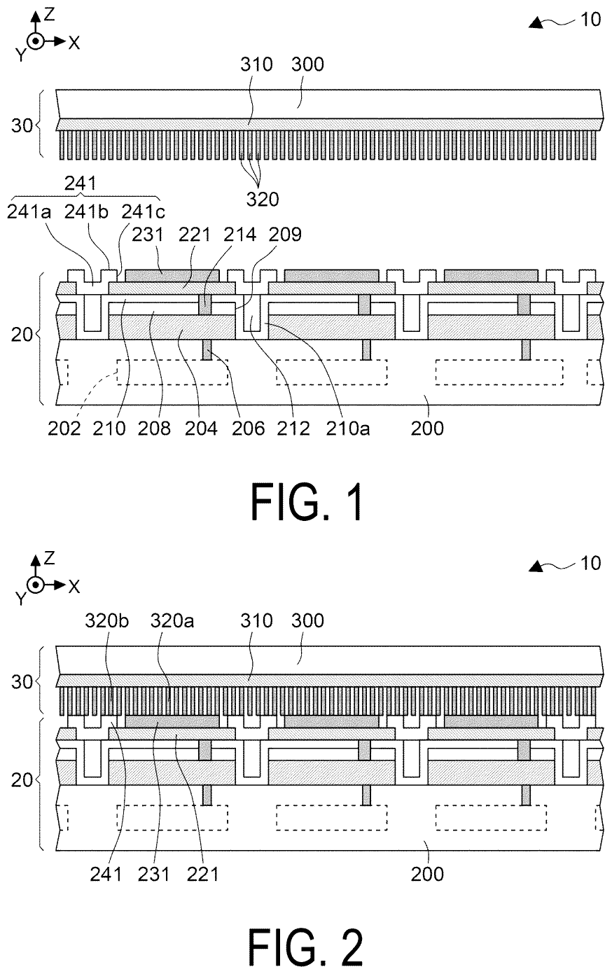

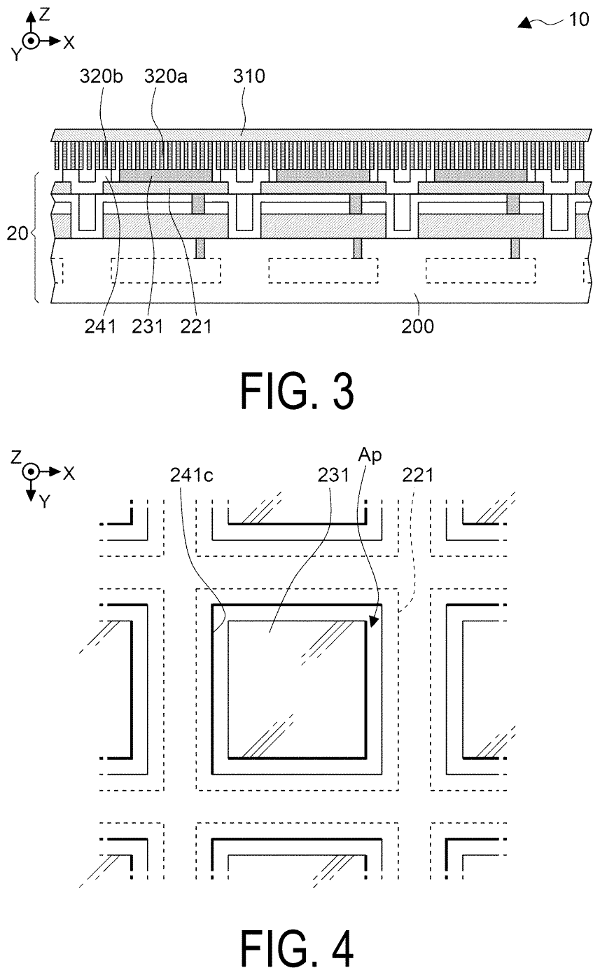

FIG. 1 to FIG. 3 are partial cross-sectional views illustrating a configuration of an electro-optical device 10 according to an embodiment. The electro-optical device 10 has a configuration obtained by bonding a driving printed wired board 20 and a light-emitting diode (LED) substrate 30 to each other, and then peeling off a substrate 300 of the LED substrate 30. Specifically, FIG. 1 is a diagram illustrating a state before the driving printed wired board 20 and the LED substrate 30 are bonded to each other, FIG. 2 is a diagram illustrating a state immediately after the driving printed wired board 20 and the LED substrate 30 are bonded to each other, and FIG. 3 is a diagram illustrating a state in which the substrate 300 is peeled from the LED substrate 30.

In the driving printed wired board 20, pixel electrodes 221 are arrayed in a matrix in a horizontal direction and a vertical direction in plan view. For convenience, the horizontal direction in the matrix array of the pixel electrodes 221 is an X direction, and the vertical direction is a Y direction. Further, in a bonded state of the driving printed wired board 20 and the LED substrate 30, a direction from the driving printed wired board 20 toward the LED substrate 30 is defined as a Z direction.

Note that the Z direction is a light emission direction in this embodiment. Further, the pixel electrode 221 is an example of a second electrode. In this description, a plan view means that the substrate is viewed from a direction perpendicular to a substrate surface, that is, a thickness direction of the substrate. A cross-sectional view means that the substrate is viewed by being cut in the direction perpendicular to the substrate surface.

As illustrated in FIG. 1, in the driving printed wired board 20, a driving circuit 202, and the like are formed on a substrate 200. The substrate 200 is, for example, a Si substrate. The driving circuit 202 is provided, for example, in one-to-one correspondence with pixels, which are the smallest units of display when viewed as a display device, and supplies current corresponding to a brightness of the pixel to elements corresponding to the pixel.

An output end of the driving circuit 202 is electrically coupled to a reflection layer 204 through a plug 206 filled in a contact hole. For the plug 206, tungsten (W) or an alloy containing tungsten is used, for example.

The reflection layer 204 is a conductive layer obtained by stacking an alloy (AlCu) film of aluminum and copper on a titanium (Ti) film, for example, and is obtained by patterning the conductive layer having a reflective property and a light-shielding property into an island shape in plan view for each pixel. The reflection layer 204 patterned in an island shape covers the driving circuit 202 in plan view. Light incident from a direction opposite to the Z direction is reflected by the reflection layer 204 and is emitted in the Z direction. In other words, the driving circuit 202 is shielded from light by the reflection layer 204, suppressing deterioration of transistor characteristics caused by light leakage or the like and enhancing emission efficiency in the Z direction. Note that the reflection layer 204 is an example of a light-shielding layer.

An insulating layer 208 is a reflection-enhancing layer for enhancing reflection characteristics of the reflection layer 204. The insulating layer 208 has an insulating property and optical transparency, and is patterned so as to cover the reflection layer 204 and have substantially the same shape as the reflection layer 204 in plan view. For example, silicon oxide is used as the insulating layer 208.

Note that a groove 209 is formed by the island-shape patterning of the reflection layer 204 and the insulating layer 208.

An insulating layer 210 covers the insulating layer 208 and is provided along the groove 209. Thus, the insulating layer 210 includes a recessed portion 210a in the vicinity of the groove 209. An embedded insulating layer 212 is provided to fill the recessed portion 210a. Silicon nitride (SiN) is used as the insulating layer 210, for example, and silicon oxide is used as the embedded insulating layer 212, for example.

The insulating layers 208 and 210 are opened by a contact hole on a per pixel basis, and the contact hole is filled with a plug 214. Surfaces of the insulating layer 210, the embedded insulating layer 212, and the plug 214 are planarized by chemical mechanical planarization (CMP) or the like. For the plug 214, tungsten (W) or an alloy containing tungsten is used, for example.

The pixel electrode 221 is provided on a per pixel basis at the surfaces thus planarized. The pixel electrode 221 is formed by patterning a conductive layer having optical transparency, such as indium tin oxide (ITO), for example, so as to overlap the reflection layer 204 in plan view and have substantially the same shape as the reflection layer 204. The pixel electrode 221 is electrically coupled to the reflection layer 204 via the plug 214.

A buffer layer 231 is provided for each pixel electrode 221. The buffer layer 231 functions as a cushioning layer and a coupling layer at the time of bonding to the LED substrate 30, and is formed by stacking a plurality of metal layers. For example, the buffer layer 231 is formed by stacking a Ti film and a Au film in this order as viewed from the pixel electrode 221.

The buffer layer 231 is provided within a range of the pixel electrode 221 in plan view. Specifically, an outer edge of the buffer layer 231 is positioned in front of an outer edge of the pixel electrode 221 as viewed from a diagonal center of the pixel electrode 221 or the buffer layer 231 in plan view.

An insulating layer 241 is stacked on the insulating layer 210, the embedded insulating layer 212, or the pixel electrode 221, and is provided covering a peripheral edge portion of the pixel electrode 221 and not covering the buffer layer 231 within a range of an opening portion Ap. For example, silicon oxide is used as the insulating layer 241.

The insulating layer 241 is divided into a portion 241a stacked on the insulating layer 210 or the embedded insulating layer 212 and a portion 241b stacked on the pixel electrode 221. An end portion 241c of the portion 241b defines an outer edge of the opening portion Ap.

FIG. 4 is a diagram illustrating shapes of the opening portion Ap, the buffer layer 231, and the pixel electrode 221 in the driving printed wired board 20 in plan view.

As illustrated in the drawing, in plan view, the buffer layer 231 is positioned in an opening area of the opening portion Ap, and the portion 241b covers the outer edge of the pixel electrode 221.

Thus, as viewed from the diagonal center of the pixel electrode 221 or the buffer layer 231 in plan view, an outer edge of the buffer layer 231, the end portion 241c of the insulating layer 241, and the outer edge of the pixel electrode 221 are positioned in this order.

Note that the buffer layer 231 and the portion 241b of the insulating layer 241 stacked on the pixel electrode 221 are aligned at substantially the same height by, for example, a CMP process.

The LED substrate 30 includes the substrate 300, a common electrode 310, and a plurality of structural bodies 320. The substrate 300 is, for example, a Si substrate, a quartz substrate, or a sapphire substrate. The common electrode 310 is a conductive layer having optical transparency, such as ITO or tin, and is stacked on the substrate 300. Note that the common electrode 310 is an example of a first electrode.

The structural bodies 320 are stacked on the common electrode 310, are columnar bodies protruding downward in the drawing, and are light-emitting bodies if conditions are satisfied. Note that the stacking order of the structural bodies 320 is downward with reference to the substrate 300. In other words, although protruding downward in the drawing, the structural bodies are, in the manufacturing process, sequentially formed upward with respect to the substrate 300 and turned over as illustrated in FIG. 1 when bonded to the driving printed wired board 20.

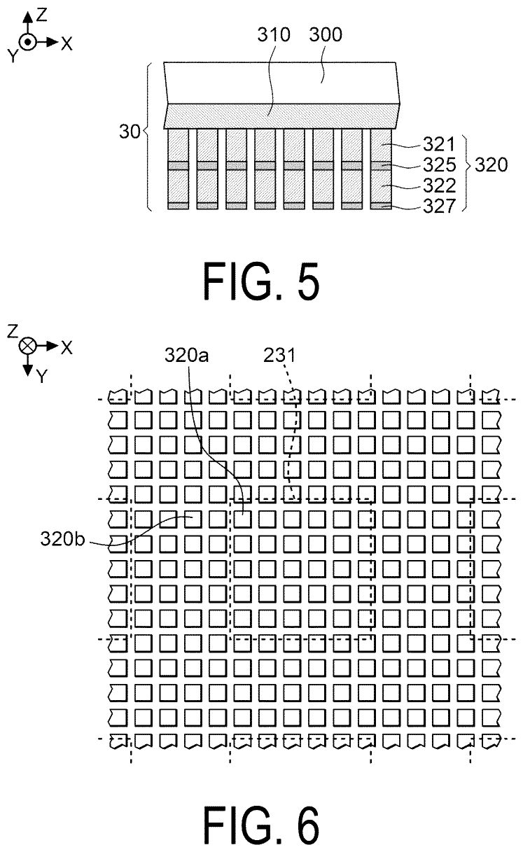

FIG. 5 is a partial cross-sectional view illustrating a detailed structure of the plurality of structural bodies 320 formed on the LED substrate 30. The drawing focuses on one of the plurality of structural bodies 320. In the structural body 320, a first semiconductor layer 321, a light emission function layer 325, a second semiconductor layer 322, and an electrode 327 are provided in this order as viewed from the common electrode 310.

The first semiconductor layer 321 is, for example, an n-type GaN layer doped with Si.

The light-emitting layer 325 is an active layer capable of generating light by being injected with a current. The light-emitting layer 325 includes, for example, a well layer and a barrier layer. The well layer and the barrier layer are i-type semiconductor layers which are not doped with impurities intentionally. The well layer is, for example, an InGaN layer. The barrier layer is, for example, a GaN layer.

The second semiconductor layer 322 is a layer of a different conduction type than that of the first semiconductor layer 321 and is, for example, a p-type GaN layer doped with Mg. The first semiconductor layer 321 and the second semiconductor layer 322 are clad layers that confine light in the light-emitting layer 325.

The electrode 331 is an electrode electrically coupled to the buffer layer 231 in the driving printed wired board 20, and is a conductive film in which, for example, a Pt film, a Ti film, and an Au film are stacked in this order as viewed from the second semiconductor layer 322.

In the structural body 320, a pin diode is constituted by the second semiconductor layer 322 of a p-type, the light emission function layer 325 of an i-type, and the first semiconductor layer 321 of an n-type. In a light-emitting device 100, when a forward bias voltage of the pin diode is applied between the electrode 331 and the common electrode 310, an electric current is injected into the light emission function layer 325 to cause recombination of electrons and holes in the light emission function layer 325. With this recombination, light is generated.

FIG. 6 is a plan view illustrating an array of the structural bodies 320 on the LED substrate 30 when viewed from the driving printed wired board 20.

The structural bodies 320 have a substantially square shape in this embodiment, and are arrayed in a matrix in the X direction and the Y direction in the same manner as the pixel electrodes 221 of the driving printed wired board 20. However, while a length of one side of the pixel electrode 221 is several μm, specifically about 3 μm in plan view, a length of one side of the square shape of the structural body 320 is, for example, from 50 nm to 500 nm, and an array pitch is about twice as large.

Note that, although the planar shape of the structural body 320 is substantially square in this embodiment, the planar shape is not limited to a square. As the planar shape of the structural body 320, any desired shape such as a circle, an ellipse, a triangle, or a hexagon, for example, may be adopted.

As illustrated in FIG. 2, such an LED substrate 30 is bonded to the driving printed wired board 20, making a protruding direction of the structural body 320 face the driving printed wired board 20.

One side of the pixel electrode 221 is 3 μm and one side of the buffer layer 231 exposed by the opening portion Ap formed by the insulating layer 241 is slightly shorter than the pixel electrode 221. However, when the driving printed wired board 20 and the LED substrate 30 are bonded to each other, a plurality of structural bodies 320 are included in one buffer layer 231. Note that the outer edge of the buffer layer 231 is indicated by a dashed line in FIG. 6.

In plan view, after bonding, among the plurality of structural bodies 320, the structural bodies 320 partially or entirely included in the buffer layer 231 are denoted by 320a, and the structural bodies 320 not included in the buffer layer 231 are denoted by 320b. The structural body 320a is an example of a first structural body, and the structural body 320b is an example of a second structural body.

When the LED substrate 30 is bonded to the driving printed wired board 20, a Au film of an outermost layer of an electrode 327 of the structural body 320a and a Au film of an outermost layer of the buffer layer 231 come into contact with each other, electrically coupling the electrode 327 of the structural body 320a to the buffer layer 231. Therefore, a current corresponding to a gray scale level is supplied to the structural bodies 320a via the driving circuit 202, the plug 206, the reflection layer 204, the plug 214, the pixel electrode 221, and the buffer layer 231, in this order. Therefore, the light emission function layer 325 of the structural body 320a functions as a light-emitting body that emits light in accordance with the gray scale level in the pixels corresponding to the pixel electrode 221.

Note that, of the light emitted from the light emission function layer 325, light traveling in the direction opposite to the Z direction is reflected by the reflection layer 204 and emitted in the Z direction.

On the other hand, at the time of bonding, the Au film of the outermost layer of the electrode 327 of the structural body 320b is either not in contact with anything or is in contact with the portion 241b of the insulating layer 241. As a result, the structural body 320b is not supplied with current from the pixel electrode 221 and is a non-light-emitting body.

In a configuration in which the structural bodies 230 are provided in one to-one correspondence with the pixel electrodes 221, high positional accuracy is required when the driving printed wired board 20 and the LED substrate 30 are bonded to each other. In particular, when the pixel electrode 221 has a size of about several μm, both substrates need be aligned with a finer sub-micron accuracy.

Due to differences in warpage amounts and warpage directions occurring in the two substrates, the relative positions of the two substrates may shift within the plane. In this case, there is a possibility that an element provided in accordance with the array pattern of the pixel electrode 221 in the driving printed wired board 20, such as, for example, a microlens, may shift, deteriorating the display quality.

Further, when the micro LED is separated and cut for each pixel, a defect in which the light emission efficiency decreases may occur. Specifically, when elements are isolated by dry etching using a reaction gas, the reaction gas damages the micro LED, resulting in a decrease in light emission efficiency.

In contrast, in this embodiment, even when the LED substrate 30 shifts in position in the X direction or the Y direction or by being rotated with respect to the driving printed wired board 20 at the time of bonding, a plurality of the structural bodies 320 are included in one buffer layer 231. Therefore, in this embodiment, when the driving printed wired board 20 and the LED substrate 30 are bonded to each other, high positional accuracy is not required even if advances are made in miniaturization.

Further, in this embodiment, with the shift in position at the time of bonding the driving printed wired board 20 and the LED substrate 30 not being problematic, even if there is an element separately provided in accordance with the array pattern of the pixel electrodes 221, deterioration of the display quality is suppressed.

In addition, in this embodiment, LED elements are not separated, and thus a decrease in light emission efficiency caused by damage does not occur.

As long as the substrates 200 and 300 are Si substrates, the electro-optical device 10 according to the embodiment can be manufactured using a known semiconductor manufacturing device.

In the embodiment described above, various modifications or applications can be made as follows.

In the embodiment, the light emission function layer 325 of the structural body 320 is horizontal with respect to the substrate surface of the substrate 300, that is, an X-Y plane, but may have, for example, a shape protruding in the Z direction.

In the embodiment, after the LED substrate 30 is bonded to the driving printed wired board 20, the substrate 300 is peeled off. However, a configuration may be adopted in which the substrate 300 is not peeled off. Specifically, when the substrate 300 has transparency, light from the light emission function layer 325 passes through the substrate 300 and is emitted in the Z direction.

Further, the substrate 200 may be a glass substrate having transparency instead of the Si substrate. When the substrate 200 is a glass substrate, it is not necessary to peel off the substrate 300 after bonding even if the substrate 300 is a Si substrate. Note that, when the substrate 200 is a glass substrate and the substrate 300 is a Si substrate, the reflection layer 204 is not provided in the driving printed wired board 20, and light from the light emission function layer 325 is emitted in a direction opposite to the Z direction, that is, from the substrate 200.

Note that, in the embodiment, strict positional accuracy is not required in the bonding of the driving printed wired board 20 and the LED substrate 30, and thus a shape of the substrate 200 and a planar shape of the substrate 300 do not need to be disk (wafer) shapes, are not limited, and thus may be, for example, rectangular shapes. A plurality of the driving printed wired boards 20 or the LED substrates 30 are formed at a substrate of a large size and then individually cut into rectangular shapes by dicing or the like after bonding. However, when the substrate 200 or 300 has a disk shape, a wasted region (dead space) increases. When the substrate 200 or 300 has a rectangular shape, a wasted region can be reduced.

Next, an electronic device to which the electro-optical device 10 according to the embodiment or the like is applied will be described. The electro-optical device 10 is suitable for application with a small pixel and high definition display. Consequently, a head-mounted display is described as an example of the electronic device.

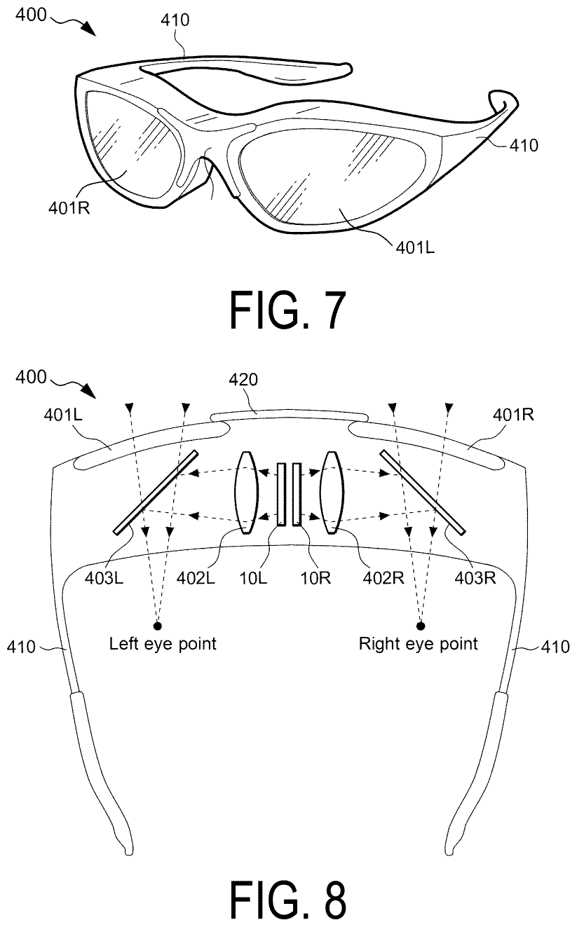

FIG. 7 is a diagram illustrating an appearance of a head-mounted display, and FIG. 8 is a diagram illustrating an optical configuration thereof.

First, as illustrated in FIG. 7, a head-mounted display 400 includes, in terms of appearance, temples 410, a bridge 420, and lenses 401L, 401R, similar to typical eyeglasses. Further, as illustrated in FIG. 8, in the head-mounted display 400, an electro-optical device 10L for a left eye and an electro-optical device 10R for a right eye are provided in the vicinity of the bridge 420 and on a back side (lower side in the drawing) of the lenses 401L, 401R.

An image display surface of the electro-optical device 10L is disposed on the left side in FIG. 8. Thus, a display image by the electro-optical device 10L is emitted via an optical lens 402L in a 9-o'clock direction in the drawing. A half mirror 403L reflects the display image by the electro-optical device 10L in a 6-o'clock direction while transmitting light incident in a 12-o'clock direction. An image display surface of the electro-optical device 10R is disposed on the right side opposite to the electro-optical device 10L. Thereby, the display image by the electro-optical device 10R is emitted via an optical lens 402R in a 3-o'clock direction in the drawing. A half mirror 403R reflects the display image by the electro-optical device 10R in a 6-o'clock direction while transmitting light incident in a 12-o'clock direction.

In this configuration, a wearer of the head-mounted display 400 can observe the display images by the electro-optical devices 10L, 10R in a see-through state in which the display image by the electro-optical devices 10L, 10R overlaps the outside.

Further, in this head-mounted display 400, in the images for both eyes with parallax, an image for the left eye is displayed by the electro-optical device 10L, and an image for the right eye is displayed by the electro-optical device 10R, making it is possible to cause the wearer to sense the displayed images as an image having a depth or a three-dimensional effect.

Note that, in addition to the head-mounted display 400, the electronic device including the electro-optical device 10 can be applied to an electronic viewing finder in a video camera, a lens-exchangeable digital camera, or the like, a display unit of a smart watch or a wearable display, a light valve for a projection type projector, and the like. Further, application is not limited to the display unit, and application can be made to a surface light-emitting element including a light-emitting source having a matrix shape, specifically, a backlight, an optical communication element, or the like.

For example, the following aspects are understood from the modes illustrated above.

An electro-optical device according to one first aspect includes a first electrode; a plurality of structural bodies, each including a first semiconductor layer having a first conductivity type electrically and being coupled to the first electrode, a second semiconductor layer of a second conductivity type, and a light emission function layer provided between the first semiconductor layer and the second semiconductor layer and configured to emit light by being injected with current; and a substrate including a second electrode and a driving circuit electrically coupled to the second electrode. The plurality of structural bodies include a first structural body provided at a position overlapping the second electrode in plan view, the second electrode being electrically coupled to the second semiconductor layer, and a second structural body provided at a position not overlapping the second electrode in plan view, the second electrode not being electrically coupled to the second semiconductor layer.

According to the electro-optical device according to the first aspect, among the plurality of structural bodies, in a plan view, the first structural body included in the second electrode functions as a light-emitting body and the second structural body not included in the second electrode does not function as a light-emitting body. Thus, strict positioning between the second electrode and the plurality of structural bodies is not required. Note that the array shape refers to a two dimensional regular array, such as a matrix shape or a delta shape.

In an electro-optical device according to a second specific aspect of the first aspect, a buffer layer having conductivity is provided at the substrate and the buffer layer is positioned between the second electrode and the second semiconductor layer. According to the electro-optical device according to the second aspect, the buffer layer can absorb an impact when the substrate and the plurality of structural bodies are bonded to each other.

In an electro-optical device according to a third specific aspect of the second aspect, an insulating layer is provided at the substrate and the insulating layer covers a peripheral edge of the second electrode in plan view and opens the second electrode. According to the electro-optical device according to the third aspect, the insulating layer is provided in a region other than the opening portion of the second electrode in plan view, making it possible to clearly separate the first structural body which functions as a light-emitting body and the second structural body which does not function as a light-emitting body.

In an electro-optical device according to a fourth specific aspect of the third aspect, the buffer layer is provided within a range of an opening portion of the insulating layer in plan view. In the electro-optical device according to the fourth aspect, with the buffer layer being provided within the range of the opening portion of the insulating layer in plan view, a structural body among the plurality of structural bodies that overlaps the buffer layer in plan view can be set as the first structural body.

In an electro-optical device according to a fifth specific aspect of the fourth aspect, the insulating layer comes into contact with at least one of the second structural bodies. In the electro-optical device according to the fifth aspect, even when the insulating layer comes into contact with the second structural body, the second structural body does not function as a light-emitting body.

An electro-optical device according to a sixth specific aspect of the first aspect further includes a light-shielding layer between the driving circuit and the second electrode in a cross-sectional view. In the electro-optical device according to the sixth aspect, the light emitted from the first structural body is blocked by the light-shielding layer before reaching the driving circuit, thereby suppressing performance degradation caused by light leakage or the like in the driving circuit.

An electronic device according to a seventh aspect includes the electro-optical device according to any one of the first to sixth aspects.

What is claimed is:

1. An electro-optical device comprising:
a first electrode;
a plurality of structural bodies, each including
a first semiconductor layer having a first conductivity type electrically and being coupled to the first electrode,
a second semiconductor layer having a second conductivity type, and
a light emission function layer provided between the first semiconductor layer and the second semiconductor layer and configured to emit light by being injected with current; and
a substrate including
a second electrode and
a driving circuit electrically coupled to the second electrode, wherein
the plurality of structural bodies include
a first structural body provided at a position overlapping the second electrode in plan view, the second electrode being electrically coupled to the second semiconductor layer and
a second structural body provided at a position not overlapping the second electrode in plan view, the second electrode not being electrically coupled to the second semiconductor layer.

2. The electro-optical device according to claim 1, wherein
a buffer layer having conductivity is provided at the substrate and
the buffer layer is positioned between the second electrode and the second semiconductor layer.

3. The electro-optical device according to claim 2, wherein
an insulating layer is provided at the substrate and
the insulating layer covers a peripheral edge of the second electrode in plan view and opens the second electrode.

4. The electro-optical device according to claim 3, wherein
the buffer layer is provided within a range of an opening portion of the insulating layer in plan view.

5. The electro-optical device according to claim 4, wherein
the insulating layer comes into contact with at least one of the second structural bodies.

6. The electro-optical device according to claim 1, further comprising:
a light-shielding layer between the driving circuit and the second electrode in a cross-sectional view.

7. An electronic device comprising the electro-optical device according to claim 1.
